(19) United States
(12) Patent Application Publication
(10) Pub. No.: US 2025/0159905 A1
(43) Pub. Date: May 15, 2025

(54) SWITCHING MEMORY ELEMENTS ACCESSED BY HETEROJUNCTION BIPOLAR TRANSISTORS

(71) Applicant: GlobalFoundries U.S. Inc., Malta, NY (US)

(72) Inventors: Halid Mulaosmanovic, Dresden (DE); Peter Baars, Dresden (DE)

(21) Appl. No.: 18/509,591

(22) Filed: Nov. 15, 2023

(51) Int. Cl. H10B 63/00; H01L 23/48; H10B 63/10; H10N 70/00

(52) U.S. Cl. CPC H10B 63/32; H01L 23/481; H10B 63/10; H10N 70/021

(57) ABSTRACT

Structures that include a switching memory element and methods of forming a structure including a switching memory element. The structure comprises a switching memory element, and a two-terminal access device including a first terminal coupled to the switching memory element, a second terminal, and a semiconductor layer between the first terminal and the second terminal. The semiconductor layer is electrically floating in the structure.

### STATEMENT REGARDING FEDERALLY SPONSORED RESEARCH OR DEVELOPMENT

This invention was made with government support under HR0011-20-3-0002 awarded by the Defense Advanced Research Projects Agency. The government has certain rights in the invention.

### BACKGROUND

The disclosure relates to integrated circuits and semiconductor device fabrication and, more specifically, to structures that include a switching memory element and methods of forming a structure that includes a switching memory element.

A resistive random-access memory device provides one type of embedded non-volatile memory technology. A bitcell of a resistive random-access memory device may include a resistive memory element and an access transistor that controls operations used to set, reset, and sense the state of the resistive memory element. Because resistive memory elements are non-volatile, bits of data are retained as stored content by the resistive memory elements when the resistive random-access memory device is unpowered. The non-volatility of a resistive random-access memory device contrasts with volatile memory technologies, such as a static random-access memory device in which the stored content is eventually lost when unpowered and a dynamic random-access memory device in which the stored content is lost unless periodically refreshed.

A resistive memory element includes a switching layer that is positioned between a bottom electrode and a top electrode. The resistive memory element can be programmed by changing the resistance across the switching layer to provide different content-storage states, namely a state characterized by a high resistance and a state characterized by a low resistance, representing the stored bits of data. The resistivity of the switching layer can be modified by applying a programming voltage across the bottom and top electrodes that is sufficient to create one or more conductive filaments bridging across the thickness of the switching layer, which sets the low-resistance state. The conductive filaments may be formed, for example, by the diffusion of a conductive species from one or both of the electrodes into the switching layer. The conductive filaments can be destroyed, also by the application of a programming voltage, to reset the resistive memory element from the low-resistance state to the high-resistance state. The content-storage state can be sensed by measuring a voltage drop across the resistive memory element after it is programmed.

Improved structures including a switching memory element and methods of forming a structure that includes a switching memory element are needed.

### SUMMARY

According to an embodiment of the invention, a structure comprises a switching memory element, and a two-terminal access device including a first terminal coupled to the switching memory element, a second terminal, and a semiconductor layer between the first terminal and the second terminal. The semiconductor layer is electrically floating in the structure.

According to an embodiment of the invention, a method comprises forming a two-terminal access device including a first terminal, a second terminal, and a semiconductor layer between the first terminal and the second terminal. The method further comprises forming a switching memory element coupled to the first terminal. The semiconductor layer is electrically floating in the structure.

### BRIEF DESCRIPTION OF THE DRAWINGS

The accompanying drawings, which are incorporated in and constitute a part of this specification, illustrate various embodiments of the invention and, together with a general description of the invention given above and the detailed description of the embodiments given below, serve to explain the embodiments of the invention. In the drawings, like reference numerals refer to like features in the various views.

FIG. 1 is a diagrammatic top view illustrating a structure including an array of heterojunction bipolar transistors at an initial stage of a fabrication method in accordance with embodiments of the invention.

FIG. 2 is a cross-sectional view taken generally along line 2-2 in FIG. 1.

FIG. 2A is a cross-sectional view taken generally along line 2A-2A in FIG. 1.

FIG. 2B is a cross-sectional view taken generally along line 2B-2B in FIG. 1.

FIGS. 3, 3A, 3B are cross-sectional views of the structure at a fabrication stage subsequent to FIGS. 1, 2, 2A, 2B.

FIGS. 4, 4A are cross-sectional views of a structure in accordance with alternative embodiments of the invention.

FIG. 5 is a cross-sectional view of a structure in accordance with alternative embodiments of the invention.

FIGS. 6, 6A, 6B are cross-sectional views of a structure in accordance with alternative embodiments of the invention.

### DETAILED DESCRIPTION

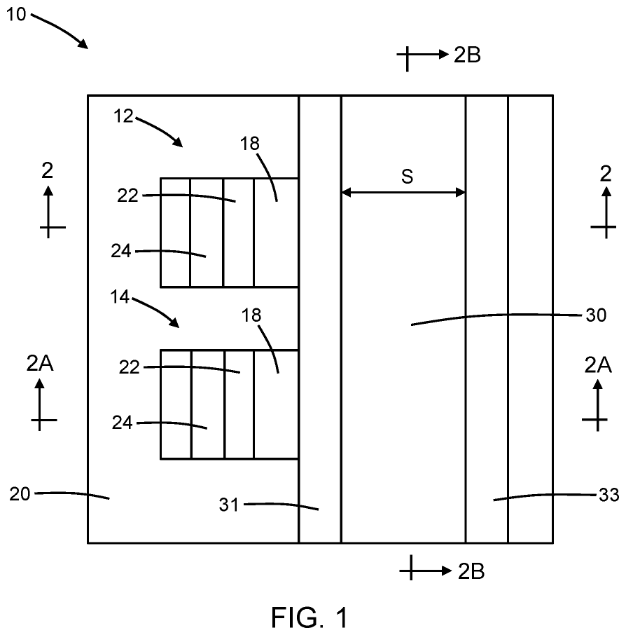

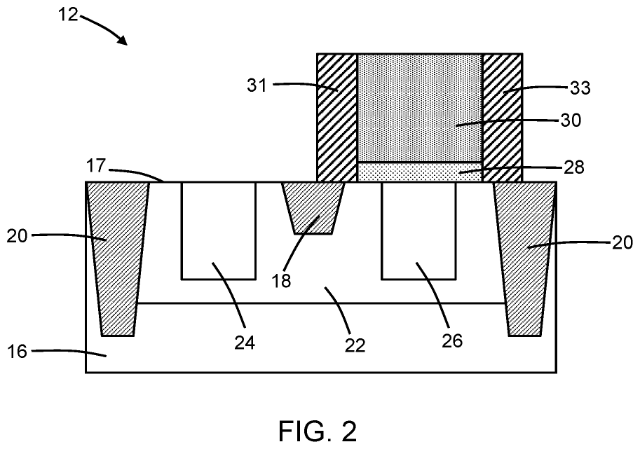

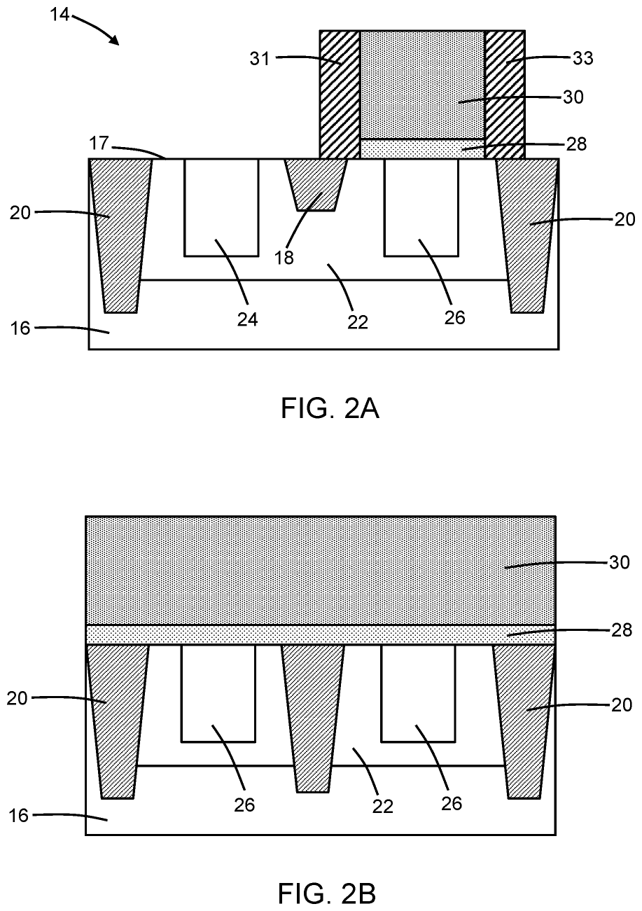

With reference to FIGS. 1, 2, 2A, 2B and in accordance with embodiments of the invention, a structure 10 for a memory device includes a heterojunction bipolar transistor 12 and a heterojunction bipolar transistor 14 that may be formed using a semiconductor substrate 16. The semiconductor substrate 16 may be comprised of a semiconductor material, such as single-crystal silicon. In an embodiment, the semiconductor substrate 16 may comprise a bulk semiconductor substrate. In an alternative embodiment, the semiconductor substrate 16 may comprise a hybrid region of a silicon-on-insulator substrate. The heterojunction bipolar transistors 12, 14 may be included in an array that includes additional heterojunction bipolar transistors and that is characterized by rows and columns.

Shallow trench isolation regions 18 and deep trench isolation regions 20 are formed that penetrate to different depths into the semiconductor substrate 16. In that regard, the deep trench isolation regions 20 extend to a greater depth in the semiconductor substrate 16 than the shallow trench isolation regions 18. The shallow trench isolation regions 18 may be formed by patterning shallow trenches with lithography and etching processes, depositing a dielectric material, such as silicon dioxide, to fill the shallow trenches, and planarizing and/or recessing the dielectric material. The deep trench isolation regions 20 may be formed by patterning deep trenches with lithography and etching processes, depositing a dielectric material, such as silicon dioxide, to fill the deep trenches, and planarizing and/or recessing the dielectric material.

A well 22 may be formed in the semiconductor substrate 16 by introducing a dopant with ion implantation under a given set of implantation conditions. The implantation conditions, such as ion species, dose, and kinetic energy, may be selected to tune the electrical and physical characteristics of the well 22. In an embodiment, the well 22 may contain a concentration of an n-type dopant, such as arsenic, that provides n-type conductivity.

The deep trench isolation regions 20 may penetrate fully through the well 22 and, in contrast, the shallow trench isolation regions 18 may penetrate only partially through the well 22. The deep trench isolation regions 20 divide the well 22 into sections, and each section of the well 22 is surrounded by the deep trench isolation regions 20. Each surrounded section of the well 22 is associated with one of the heterojunction bipolar transistors 12, 14. Each shallow trench isolation region 18 is disposed inside the perimeter of one of the surrounded sections of the well 22 such that each section of the well 22 is fully divided into a pair of adjacent subsections. A portion of each section of the well 22 is disposed beneath the associated shallow trench isolation region 18 such that each pair of adjacent subsections of the well 22 is electrically connected.

Doped regions 24, 26 are formed in the different subsections of each section of the well 22. The shallow trench isolation region 18 in each section of the well 22 is laterally disposed between the doped region 24 and the doped region 26. The doped regions 24, 26 may be formed in each section of the well 22 by introducing a dopant with ion implantation under a given set of implantation conditions. The implantation conditions, such as ion species, dose, and kinetic energy, may be selected to tune the electrical and physical characteristics of the doped regions 24, 26. The semiconductor material of the doped regions 24, 26 has the same conductivity type as the semiconductor material of the well 22. In an embodiment, the semiconductor material of the doped regions 24, 26 may receive and contain an n-type dopant, such as arsenic, that provides n-type conductivity. In an embodiment, the semiconductor material of the doped regions 24, 26 may contain a higher concentration of the n-type dopant than the well 22. The section of the well 22 and the doped regions 24, 26 of each of the heterojunction bipolar transistors 12, 14 may constitute a semiconductor region defining a terminal, such as a collector.

A semiconductor layer 28 and a semiconductor layer 30 may be disposed in a layer stack on the semiconductor substrate 16. The semiconductor layers 28, 30 may extend laterally across the sections of the well 22 associated with the heterojunction bipolar transistors 12, 14. The semiconductor layers 28, 30 include portions that overlap with the doped region 26 in each section of the wall 22 associated with one of the heterojunction bipolar transistors 12, 14. The semiconductor layer 30 is separated from a top surface 17 of the semiconductor substrate 16 by the underlying semiconductor layer 28.

The semiconductor layer 28 may be formed by epitaxially growing, or depositing, a layer comprised of a semiconductor material and patterning the layer with lithography and etching processes. In an embodiment, the semiconductor layer 28 may be comprised of silicon-germanium including silicon and germanium with the silicon content ranging from 95 atomic percent to 50 atomic percent and the germanium content ranging from 5 atomic percent to 50 atomic percent. The semiconductor layer 28 may be doped to have an opposite conductivity type from the well 22 and the doped regions 24, 26. In an embodiment, the semiconductor layer 28 may be doped with a concentration of a dopant, such as a p-type dopant like boron that provides p-type conductivity.

The semiconductor layer 30 over the doped region 26 in each section of the well 22 may define a terminal, such as an emitter, of the particular heterojunction bipolar transistors 12, 14. The semiconductor layer 30 may be formed by epitaxially growing, or depositing, a layer comprised of a semiconductor material and patterning the layer with lithography and etching processes. In an embodiment, the semiconductor layers 28, 30 may be concurrently patterned to form the layer stack. The semiconductor layer 30 may be doped to have the same conductivity type as the well 22 and the doped regions 24, 26. The semiconductor layer 30 may be doped to have an opposite conductivity type from the underlying semiconductor layer 28. In an embodiment, the semiconductor layer 30 may be comprised of a semiconductor material, such as polysilicon, that is doped with a concentration of an n-type dopant, such as arsenic, that provides n-type conductivity.

Dielectric spacers 31, 33, which comprised of one or more dielectric materials that are electrical insulators, may be formed adjacent to the layer stack including the semiconductor layers 28, 30. In an embodiment, the dielectric spacers 31, 33 may directly contact the top surface 17 of the semiconductor substrate 16. In an embodiment, the layer stack including the semiconductor layers 28, 30 is disposed laterally between the dielectric spacer 31 and the dielectric spacer 33. In an embodiment, the semiconductor layer 28 may terminate in a lateral direction at the dielectric spacer 31 and at the dielectric spacer 33. In an embodiment, the semiconductor layer 30 of each of the heterojunction bipolar transistors 12, 14 may terminate in a lateral direction at the dielectric spacer 31 and at the dielectric spacer 33. In an embodiment, the semiconductor layer 28 and the semiconductor layer 30 may each terminate in a lateral direction at the dielectric spacer 31 and at the dielectric spacer 33. In an embodiment, the semiconductor layer 28 may be coextensive with each of the dielectric spacers 31, 33. In an embodiment, the semiconductor layer 30 may be coextensive with each of the dielectric spacers 31, 33. In an embodiment, the semiconductor layer 28 and the semiconductor layer 30 may be coextensive with each of the dielectric spacers 31. The dielectric spacer 31 may be separated from the dielectric spacer 33 by a spacing S, and the semiconductor layers 28, 30 may have respective width dimensions that are equal to the spacing S.

The semiconductor layer 28 overlaps with the subsection of the well 22 that includes the doped region 26 of each of the heterojunction bipolar transistors 12, 14. The semiconductor layer 30 overlaps with the semiconductor layer 28. In an embodiment, the semiconductor layers 28, 30 may be centered above the doped region 26 of each of the heterojunction bipolar transistors 12, 14. The semiconductor layer 28 is positioned in a vertical direction between the semiconductor layer 30 and the doped region 26 of each of the heterojunction bipolar transistors 12, 14.

A field-effect transistor (not shown) may be formed on a portion of the semiconductor substrate 16 that includes an intact device layer and an intact buried oxide layer of a silicon-on-insulator substrate. In an embodiment, the intact device layer of the silicon-on-insulator substrate may have a thickness in a range of about 4 nanometers to about 20 nanometers, and the field-effect transistor may be characterized as a fully-depleted silicon-on-insulator (FDSOI) device structure.

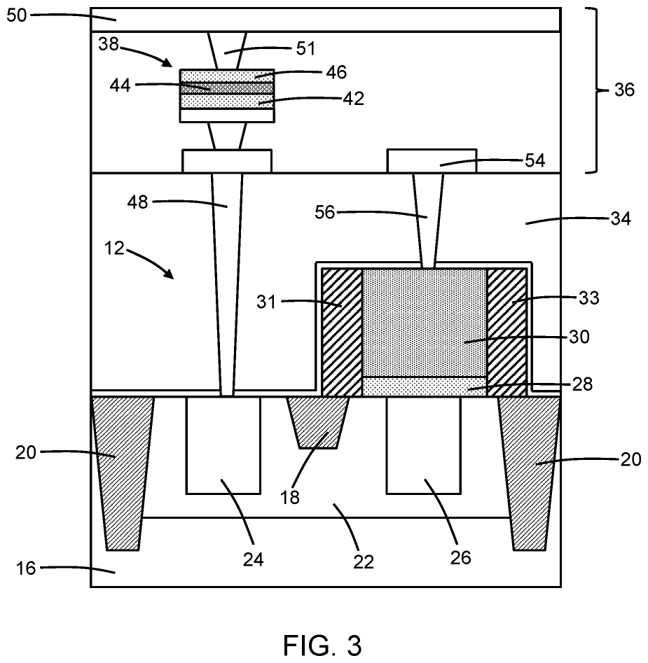

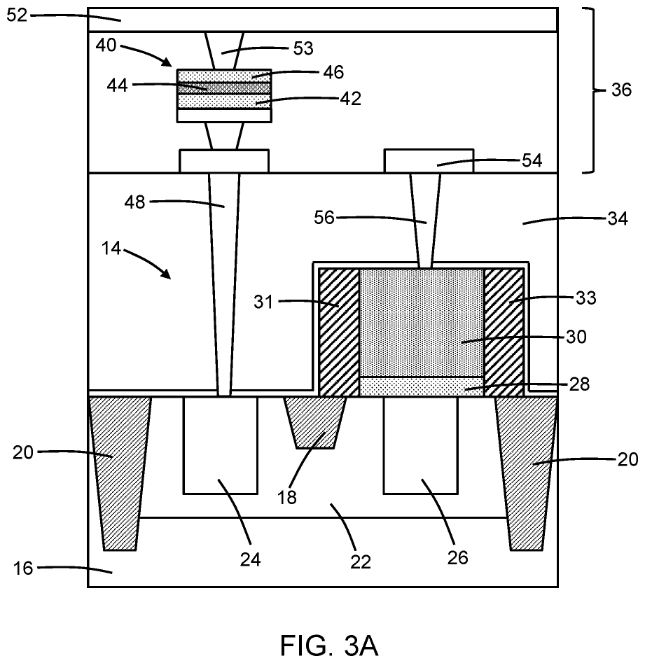

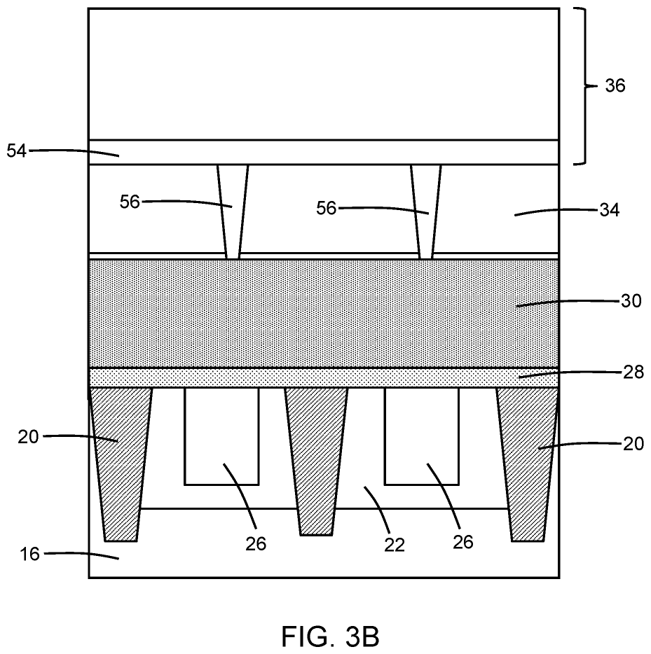

With reference to FIGS. 3, 3A, 3B in which like reference numerals refer to like features in FIGS. 1, 2, 2A, 2B and at a subsequent fabrication stage, a dielectric layer 34 comprised of a dielectric material, such as silicon dioxide, is deposited and planarized. A back-end-of-line stack 36 is formed over the heterojunction bipolar transistors 12, 14, the semiconductor substrate 16, and the dielectric layer 34. The back-end-of-line stack 36, which may be fabricated by back-end-of-line processing, includes interlayer dielectric layers and vertical interconnections 48 having metal islands, vias, and/or contacts as metal features arranged in the interlayer dielectric layers. The interlayer dielectric layers of the back-end-of-line stack 36 may be comprised of dielectric materials, such as silicon dioxide and silicon nitride, and the vertical interconnections 48 may be comprised of one or more metals, such as copper, aluminum, tungsten, and/or a metal silicide.

Switching memory elements 38, 40 are disposed in the back-end-of-line stack 36. In an embodiment, each of the switching memory elements 38, 40 may be a resistive non-volatile memory element that includes a bottom electrode 42 coupled by one of the vertical interconnections 48 to the doped region 24 associated with one of the heterojunction bipolar transistors 12, 14, a switching layer 44, and a top electrode 46. The bottom electrode 42 may be comprised of a metal, such as tantalum, titanium nitride, tantalum nitride, or a combination thereof. The switching layer 44 may be comprised of a dielectric material, such as hafnium oxide, magnesium oxide, tantalum oxide, titanium oxide, aluminum oxide, silicon nitride, silicon dioxide, or a combination thereof. The top electrode 46 may be comprised of a metal, such as tungsten, titanium nitride, tantalum nitride, platinum, or a combination thereof. The bottom electrode 42 and the top electrode 46 of each of the switching memory elements 38, 40 may respectively define a cathode and an anode.

In an alternative embodiment, the switching memory elements 38, 40 may be phase change memory elements in which the switching layer 44 is comprised of a phase change material. The phase change material, which may a chalcogenide glass such as Ge₂Sb₂Te₅, may be heated to provide either an amorphous phase or a crystalline phase that respectively define a high-resistance state and a low-resistance state. In that regard, the phase change material of the switching layer 44 may be heated above its melting point by applying an electrical current between the bottom electrode 42 and the top electrode 46. Depending on the current magnitude and pulsing of the current, the melted phase change material can either crystallize or remain amorphous upon cooling below the melting point.

A bit line 50, a bit line 52, and a word line 54 are provided by metal features located in the back-end-of-line stack 36. The bit line 50 may be electrically and physically coupled by a contact 51 to the top electrode 46 of the switching memory element 38, and the bit line 52 may be electrically and physically coupled by a contact 53 to the top electrode 46 of the switching memory element 40. The word line 54 may be electrically and physically coupled by contacts 56 to the semiconductor layer 30. The contacts 56 connected to the semiconductor layer 30 may be disposed over the different sections of the well 22.

The heterojunction bipolar transistors 12, 14 provide access transistors respectively used to program the switching memory elements 38, 40. More specifically, the switching memory element 38 can be programmed under the control of the heterojunction bipolar transistor 12 between the high-resistance state and the low-resistance state, the switching memory element 40 can be programmed under the control of the heterojunction bipolar transistor 14 between the high-resistance state and the low-resistance state, and the switching memory elements 38, 40 can also be sensed under the control of the heterojunction bipolar transistors 12, 14.

The semiconductor layer 28 is uncontacted and electrically floating in the structure 10. As a result, each of the heterojunction bipolar transistors 12, 14 lacks a terminal associated with the semiconductor layer 28 although a portion of the semiconductor layer 28 is disposed over each of the doped regions 24. During use, the heterojunction bipolar transistors 12, 14 may operate in a latch-up operation mode as two-terminal access devices instead of operating as conventional three-terminal access devices because the semiconductor layer 28 is electrically floating. The two-terminal access devices may offer advantageously large on-currents during the operation of the switching memory elements 38, 40, as well as high non-linearity, improved reliability, and fast switching, in comparison with conventional three-terminal access devices, such as conventional heterojunction bipolar transistors having a base layer that is non-floating.

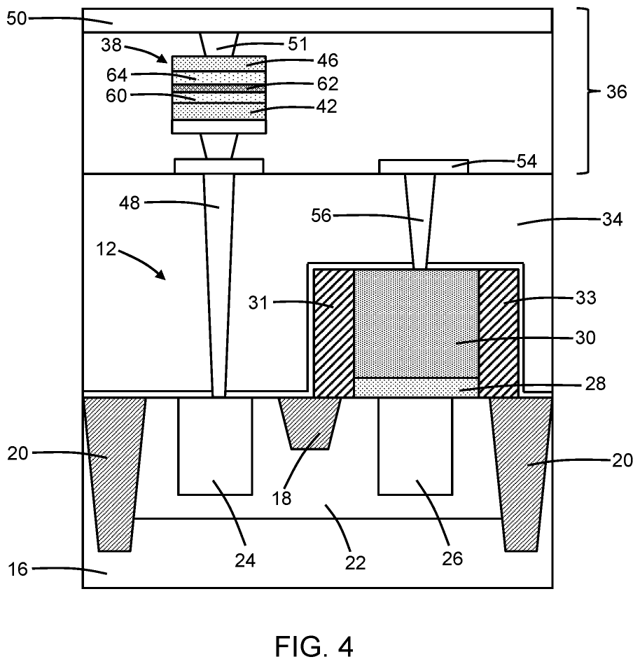

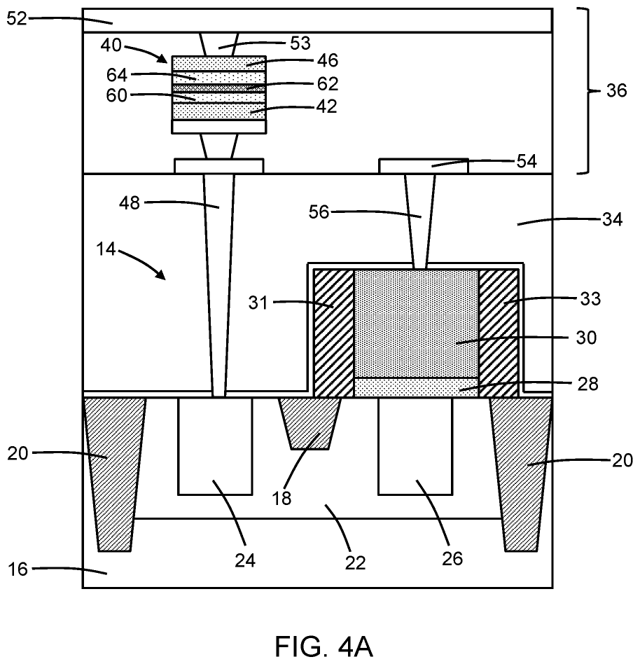

With reference to FIGS. 4, 4A and in accordance with alternative embodiments of the invention, the switching memory elements 38, 40 may include magnetic-tunneling-junction layer stacks disposed between the bottom electrode 42 and the top electrode 46. Each magnetic-tunneling-junction layer stack may include a pinned or fixed layer 60, a free layer 64, and a tunnel barrier layer 62 arranged between the fixed layer 60 and the free layer 64. The magnetization of the fixed layer 60 is fixed in its magnetic orientation, and the magnetization of the free layer 64 can be switched relative to the fixed layer 60 by, for example, the application of a programming current. In particular, the magnetic orientation of the free layer 64 may be programmed by the programming current relative to the magnetic orientation of the fixed layer 60 to have either a parallel state with low electrical resistance across the magnetic-tunneling-junction layer stack or an antiparallel state with high electrical resistance across the magnetic-tunneling-junction layer stack.

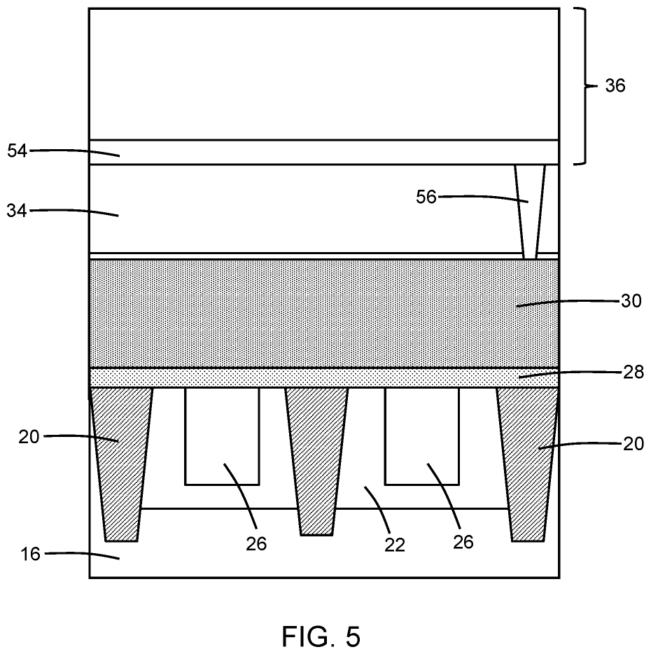

With reference to FIG. 5 and in accordance with alternative embodiments of the invention, the contacts 56 coupled to the semiconductor layer 30 may be disposed over the deep trench isolation regions 20 instead of being disposed over the sections of the well 22. As a result, the contacts 56 are laterally offset from the active region of each of the heterojunction bipolar transistors 12, 14.

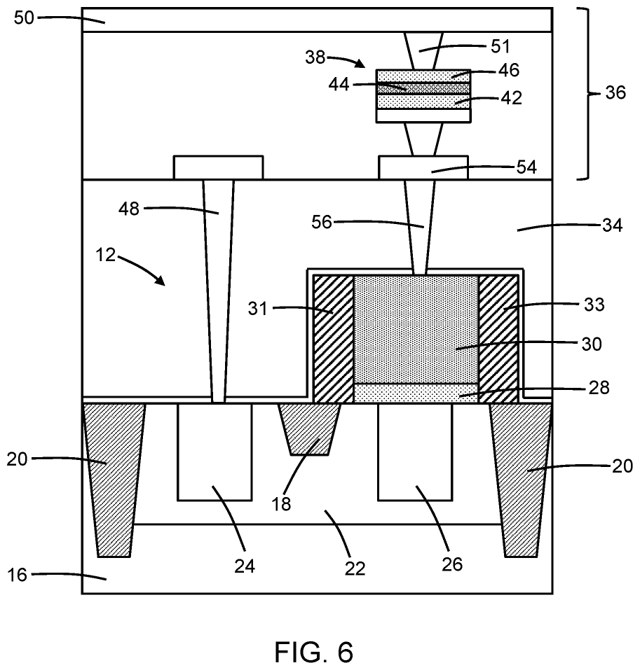

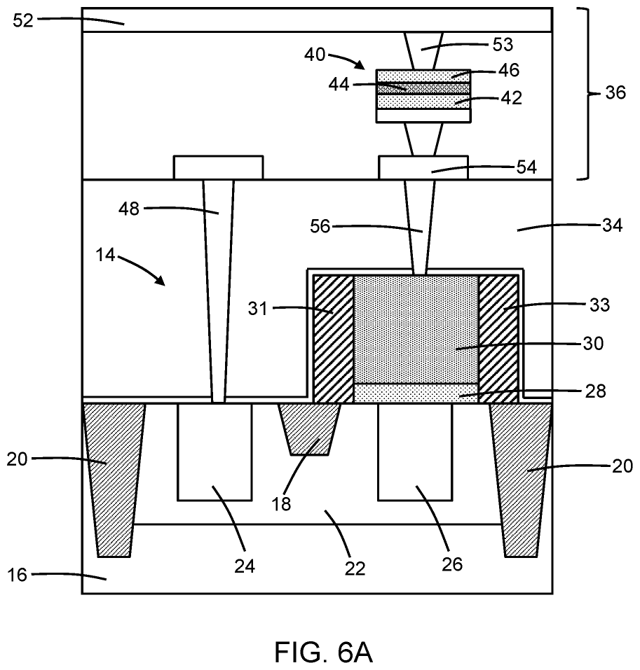

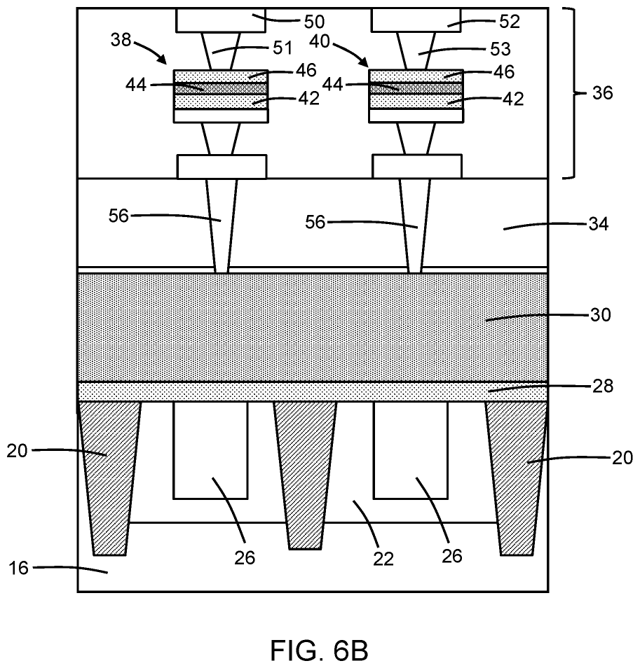

With reference to FIGS. 6, 6A, 6B and in accordance with alternative embodiments of the invention, the structure 10 may be reconfigured such that the switching memory element 38 is coupled to a different terminal of the heterojunction bipolar transistor 12 and the switching memory element 40 is coupled to a different terminal of the heterojunction bipolar transistor 14. In that regard, the switching memory element 38 may be physically and electrically coupled to the portion of the semiconductor layer 30 associated with the heterojunction bipolar transistor 12, and the switching memory element 40 may be physically and electrically coupled to the portion of the semiconductor layer 30 associated with the heterojunction bipolar transistor 14. The reconfigured structure 10 may be deployed in a crossbar array, which offers a compact memory integration.

The methods as described above are used in the fabrication of integrated circuit chips. The resulting integrated circuit chips can be distributed by the fabricator in raw wafer form (e.g., as a single wafer that has multiple unpackaged chips), as a bare die, or in a packaged form. The chip may be integrated with other chips, discrete circuit elements, and/or other signal processing devices as part of either an intermediate product or an end product. The end product can be any product that includes integrated circuit chips, such as computer products having a central processor or smartphones.

References herein to terms modified by language of approximation, such as “about”, “approximately”, and “substantially”, are not to be limited to the precise value specified. The language of approximation may correspond to the precision of an instrument used to measure the value and, unless otherwise dependent on the precision of the instrument, may indicate a range of +/−10% of the stated value(s).

References herein to terms such as “vertical”, “horizontal”, etc. are made by way of example, and not by way of limitation, to establish a frame of reference. The term “horizontal” as used herein is defined as a plane parallel to a conventional plane of a semiconductor substrate, regardless of its actual three-dimensional spatial orientation. The terms “vertical” and “normal” refer to a direction in the frame of reference perpendicular to the horizontal, as just defined. The term “lateral” refers to a direction in the frame of reference within the horizontal plane.

A feature “connected” or “coupled” to or with another feature may be directly connected or coupled to or with the other feature or, instead, one or more intervening features may be present. A feature may be “directly connected” or “directly coupled” to or with another feature if intervening features are absent. A feature may be “indirectly connected” or “indirectly coupled” to or with another feature if at least one intervening feature is present. A feature “on” or “contacting” another feature may be directly on or in direct contact with the other feature or, instead, one or more intervening features may be present. A feature may be “directly on” or in “direct contact” with another feature if intervening features are absent. A feature may be “indirectly on” or in “indirect contact” with another feature if at least one intervening feature is present. Different features may “overlap” if a feature extends over, and covers a part of, another feature.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A structure comprising:
a first switching memory element; and
a two-terminal access device including a first terminal coupled to the first switching memory element, a second terminal, and a first semiconductor layer between the first terminal and the second terminal,
wherein the first semiconductor layer is electrically floating in the structure.

2. The structure of claim 1 wherein the first switching memory element is a resistive random access memory element that includes a first electrode, a second electrode, and a switching layer between the first electrode and the second electrode.

3. The structure of claim 1 wherein the first switching memory element is a phase change memory element that includes a first electrode, a second electrode, and a layer of phase change material between the first electrode and the second electrode.

4. The structure of claim 1 wherein the first switching memory element is a magnetoresistive memory element that includes a free layer, a fixed layer, and a tunnel barrier layer between the free layer and the fixed layer.

5. The structure of claim 1 wherein the first semiconductor layer comprises silicon-germanium.

6. The structure of claim 1 further comprising:
a semiconductor substrate,
wherein the first terminal comprises a well in the semiconductor substrate and a first doped region in the well, and the first switching memory element is coupled to the first doped region.

7. The structure of claim 6 wherein the first semiconductor layer is disposed on a portion of the well, the first terminal comprises a second doped region disposed in the portion of the well, and further comprising:
a shallow trench isolation region in the semiconductor substrate, the shallow trench isolation region disposed laterally between the first doped region and the second doped region.

8. The structure of claim 1 further comprising:
a semiconductor substrate,
wherein the first semiconductor layer is disposed on a portion of the semiconductor substrate, the first terminal is a second semiconductor layer disposed on the first semiconductor layer, and the first switching memory element is coupled to the second semiconductor layer.

9. The structure of claim 8 further comprising:
a second switching memory element coupled to the second semiconductor layer.

10. The structure of claim 9 further comprising:
a back-end-of-line stack disposed on the semiconductor substrate,
wherein the first switching memory element and the second switching memory element are disposed in the back-end-of-line stack.

11. The structure of claim 8 wherein the semiconductor substrate has a top surface, the first semiconductor layer directly contacts the top surface of the semiconductor substrate, and further comprising:
a first dielectric spacer in direct contact with the top surface of the semiconductor substrate; and
a second dielectric spacer in direct contact with the top surface of the semiconductor substrate,
wherein the first semiconductor layer and the second semiconductor layer are disposed between the first dielectric spacer and the second dielectric spacer.

12. The structure of claim 11 wherein the first dielectric spacer is separated from the second dielectric spacer by a spacing, and the first semiconductor layer and the second semiconductor layer have respective widths that are each equal to the spacing.

13. The structure of claim 11 wherein the first semiconductor layer and the second semiconductor layer each terminate at the first dielectric spacer, and the first semiconductor layer and the second semiconductor layer each terminate at the second dielectric spacer.

14. The structure of claim 1 further comprising:
a semiconductor substrate,
wherein the first semiconductor layer is disposed on a portion of the semiconductor substrate.

15. The structure of claim 14 the semiconductor substrate has a top surface, the first semiconductor layer directly contacts the top surface of the semiconductor substrate, and further comprising:
a first dielectric spacer in direct contact with the top surface of the semiconductor substrate; and
a second dielectric spacer in direct contact with the top surface of the semiconductor substrate,
wherein the first semiconductor layer is disposed between the first dielectric spacer and the second dielectric spacer.

16. The structure of claim 15 wherein the second terminal is a second semiconductor layer is disposed on the first semiconductor layer, and the second semiconductor layer is disposed between the first dielectric spacer and the second dielectric spacer.

17. The structure of claim 16 wherein the first semiconductor layer and the second semiconductor layer are coextensive with the spacer.

18. The structure of claim 16 wherein the first semiconductor layer and the second semiconductor layer terminate at the spacer.

19. The structure of claim 14 further comprising:
a back-end-of-line stack on the semiconductor substrate,
wherein the first switching memory element is disposed in the back-end-of-line stack above the two-terminal access device.

20. A method comprising:
forming a two-terminal access device including a first terminal, a second terminal, and a semiconductor layer between the first terminal and the second terminal; and
forming a switching memory element coupled to the first terminal,
wherein the semiconductor layer is electrically floating in the structure.
